(19) United States
(12) Patent Application Publication
(10) Pub. No.: US 2020/0039004 A1
(43) Pub. Date: Feb. 6, 2020

(54) CUTTING DEVICE FOR CUTTING COMPOSITE MATERIAL

(71) Applicant: CohPros International Co., Ltd., Kaohsiung City (TW)

(72) Inventors: SHIH-SHENG LIN, Kaohsiung City (TW); CHIH-WEI YU, Taipei City (TW)

(21) Appl. No.: 16/276,251

(22) Filed: Feb. 14, 2019

(30) Foreign Application Priority Data
Aug. 1, 2018 (TW) 107210505

(51) Int. Cl. B23K 26/38; B23K 26/082; B23K 26/0622; H01L 21/78

(52) U.S. Cl. CPC B23K 26/38; H01L 21/78; B23K 26/0622; B23K 26/082

(57) ABSTRACT

A cutting device for cutting a composite material includes a carrier module and a laser generating module. The carrier module is used for carrying the composite material. The laser generating module is used for providing a laser beam. The laser generating module includes a laser scanning writer for providing a laser source, and a laser path adjuster located on a scanning path of the laser source. The laser path adjuster adjusts the scanning path of the laser beam or the carrier module carries the composite material to move, so that a cutting area formed by projecting the laser beam onto the composite material is offset parallel.

### CROSS-REFERENCE TO RELATED PATENT APPLICATION

This application claims the benefit of priority to Taiwan Patent Application No. 107210505, filed on Aug. 1, 2018. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the present disclosure described herein. All references cited and discussed in this specification are incorporated herein by reference in their entireties and to the same extent as if each reference was individually incorporated by reference.

### FIELD OF THE PRESENT DISCLOSURE

The present disclosure relates to a cutting device, and more particularly to a cutting device for cutting a composite material.

### BACKGROUND OF THE PRESENT DISCLOSURE

Existing semiconductor fabrication techniques such as wafer dicing, scribing or patterning are still primarily performed by using metal cutting blades. Such metal cutting blades can cut semiconductor materials such as gallium arsenide and silicon carbide. However, in order to avoid damaging the cutting surface, the dicing speed must be controlled within a limited range, which leads to difficulty in product capacity improvement.

On the other hand, with the continuous progress in the technology of wafer producing, the technique of forming a composite material by sputtering and depositing a layered film of various materials on the wafer surface has been developed. However, a composite material so formed has a greater thickness than existing wafers, and while the composite material can still be cut with the aid of an existing laser cutting technology, the cutting surface of the composite material can easily be deformed thereby, which affects subsequent processing.

### SUMMARY OF THE PRESENT DISCLOSURE

In response to the above-referenced technical inadequacies, the present disclosure provides a cutting device for cutting a composite material.

In one aspect, the present disclosure provides a cutting device for cutting a composite material including a carrier module and a laser generating module. The carrier module is used for carrying the composite material. The laser generating module is used for providing a laser beam. The laser generating module includes a laser scanning writer for providing a laser source, and a laser path adjuster located on a scanning path of the laser source. The laser path adjuster adjusts the scanning path of the laser beam or the carrier module carries the composite material to move, so that a cutting area formed by projecting the laser beam onto the composite material is offset parallel.

Therefore, through the technical features of “a laser generating module for providing a laser beam,” “the laser generating module includes a laser scanning writer for providing a laser source and a laser path adjuster on the scanning path of the laser light source,” and “the cutting area formed by projecting the laser beam on the composite material is offset parallel by the adjustment of the scanning path of the laser beam by the laser path adjuster, or the moving of the composite material through the carrier module,” the cutting device for cutting the composite material provided by the present disclosure can form a plurality of the cutting areas at different positions on the composite material, and gradually deepen the cutting depth by repeated and continuing projection of the laser beam, so as to cut through the composite material.

These and other aspects of the present disclosure will become apparent from the following description of certain embodiments taken in conjunction with the following drawings and their captions, although variations and modifications therein may be affected without departing from the spirit and scope of the novel concepts of the present disclosure.

### BRIEF DESCRIPTION OF THE DRAWINGS

The present disclosure will become more fully understood from the detailed description and the accompanying drawings, in which:

FIG. 1 is a schematic structural view of a cutting device for cutting a composite material according to a first embodiment of the present disclosure.

FIG. 2 is a schematic structural view of a laser scanning writer of the cutting device for cutting the composite material according to the first embodiment of the present disclosure.

FIG. 3 is a first top view of the cutting device for cutting the composite material forming a cutting area on the composite material by a laser beam according to the first embodiment of the present disclosure.

FIG. 4 is a second top view of the cutting device for cutting the composite material forming the cutting area on the composite material by the laser beam according to the first embodiment of the present disclosure.

FIG. 5 is a third top view of the cutting device for cutting the composite material forming the cutting area on the composite material by the laser beam according to the first embodiment of the present disclosure.

FIG. 6 is a fourth top view of the cutting device for cutting the composite material forming a cutting area on the composite material by a laser beam according to the first embodiment of the present disclosure.

FIG. 7 is a fifth top view of the cutting device for cutting the composite material forming a cutting area on the composite material by a laser beam according to the first embodiment of the present disclosure.

FIG. 8 is a first schematic diagram of the cutting device cutting the composite material by the laser beam according to the first embodiment of the present disclosure.

FIG. 9 is a second schematic diagram of the cutting device cutting the composite material by the laser beam according to the first embodiment of the present disclosure.

FIG. 10 is a third schematic diagram of the cutting device cutting the composite material by the laser beam according to the first embodiment of the present disclosure.

FIG. 11 is a fourth schematic diagram of the composite material cut by the laser beam of the cutting device according to the first embodiment of the present disclosure.

FIG. 12 is a first schematic diagram of the cutting device cutting the composite material by a laser beam according to a second embodiment of the present disclosure.

FIG. 13 is a second schematic diagram of the cutting device cutting the composite material by a laser beam according to the second embodiment of the present disclosure.

FIG. 14 is a third schematic diagram of the cutting device cutting the composite material by a laser beam according to the second embodiment of the present disclosure.

FIG. 15 is a fourth schematic diagram of the composite material cut by the laser beam of the cutting device according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

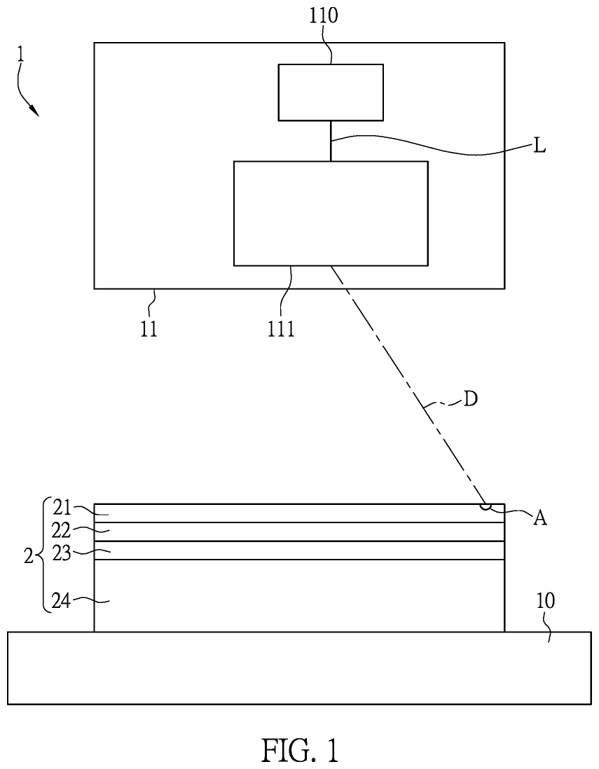

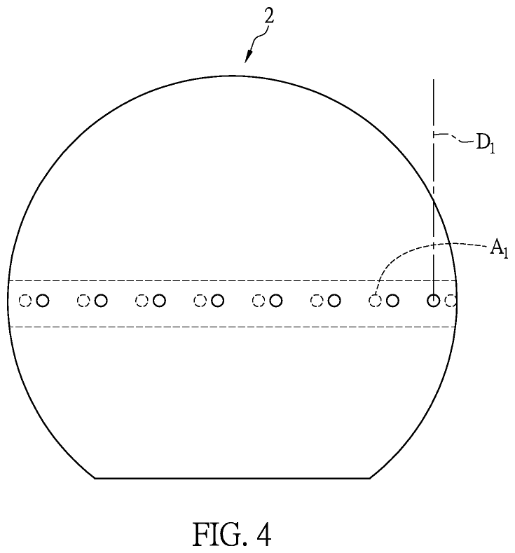

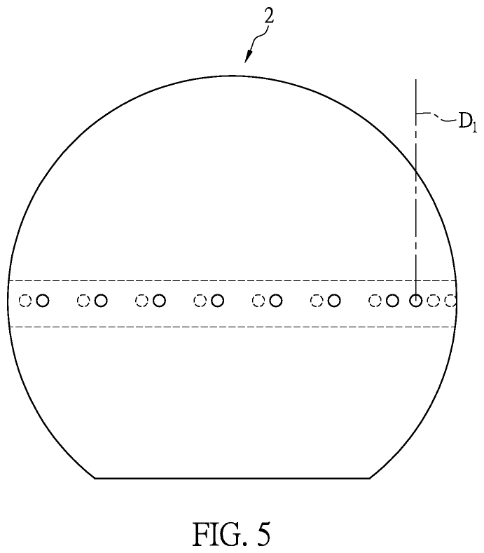

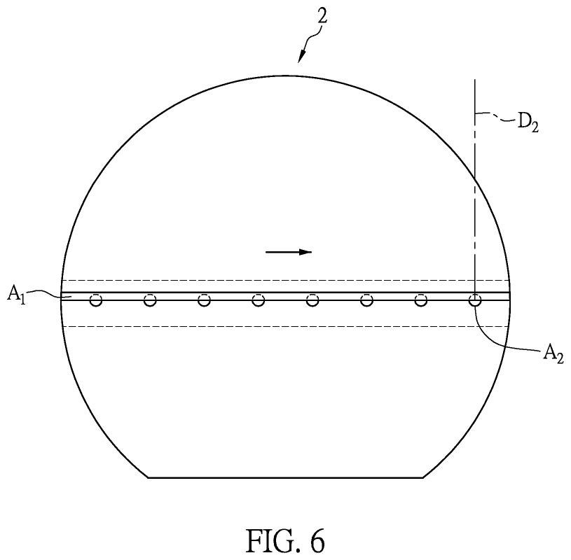

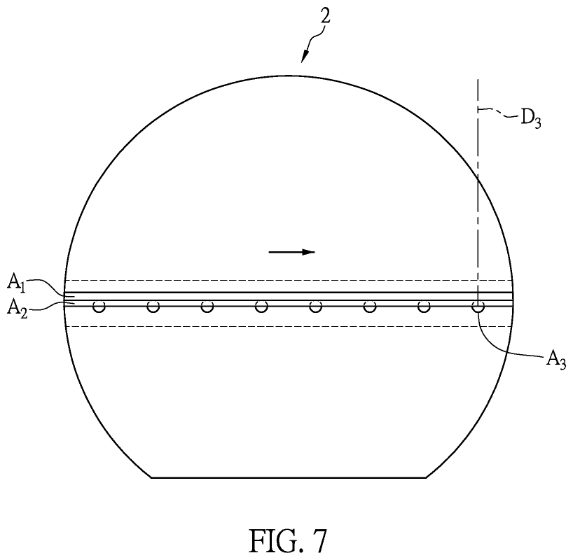

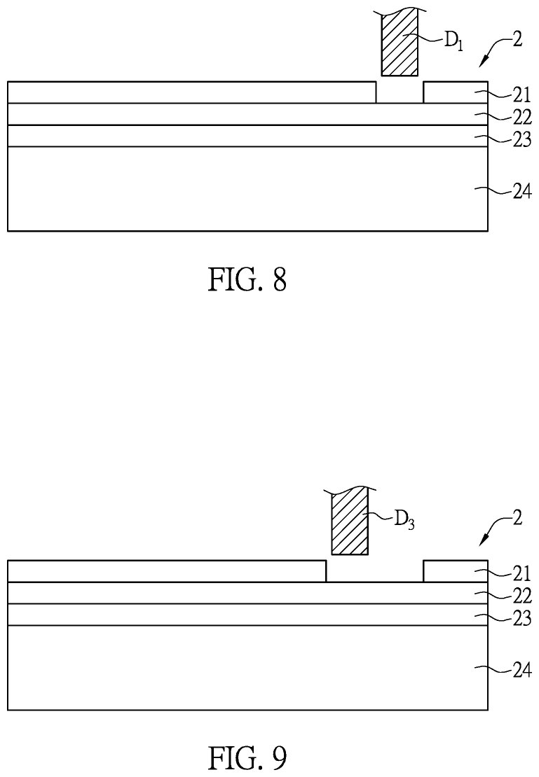

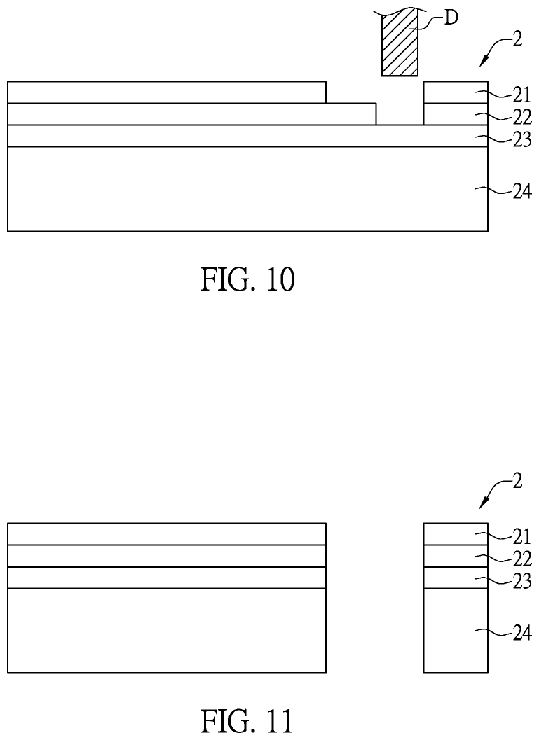

Reference is made to FIG. 1 to FIG. 11, which are respectively a schematic structural view of a cutting device 1 for cutting a composite material 2 according to a first embodiment of the present disclosure, a schematic structural view of a laser scanning writer 110 of the cutting device 1 for cutting the composite material 2 according to the first embodiment of the present disclosure, the first to fifth top views of the cutting device 1 for cutting the composite material 2 forming cutting areas A₁ to A₃ on the composite material 2 by laser beams D₁ to D₃ according to the first embodiment of the present disclosure, and the first to fourth schematic diagrams of the cutting device cutting the composite material by a laser beam according to the first embodiment of the present disclosure. As shown in the figures, the first embodiment of the present disclosure provides a cutting device 1 for cutting a composite material 2, which includes a carrier module 10 and a laser generating module 11. The carrier module 10 is used to carry the composite material 2. The laser generating module 11 is configured to provide a laser beam D. The laser generating module 11 includes a laser scanning writer 110 for providing a laser source L and a laser path adjuster 111 located on the scanning path of the laser source L. The scanning path of the laser beam D can be adjusted by the laser path adjuster 111, or the composite material 2 can be carried and moved by the carrier module 10, such that a cutting area A formed by projecting the laser beam D onto the composite material 2 is offset parallel.

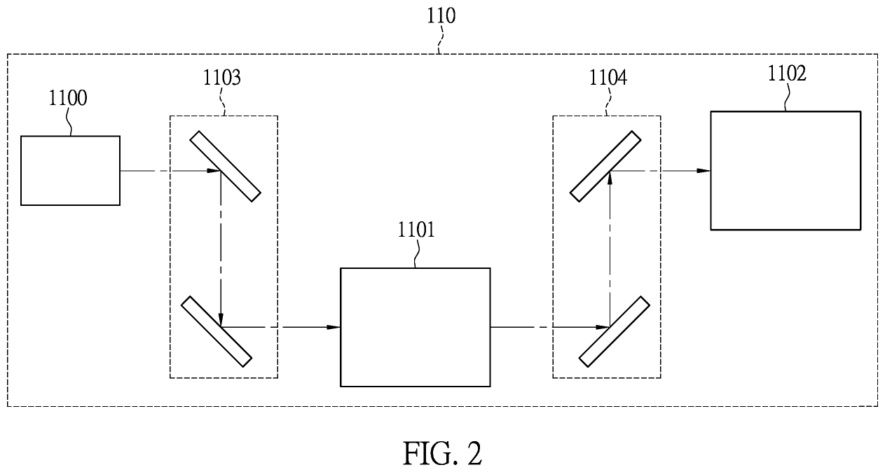

Specifically, the cutting device 1 for cutting the composite material 2 of the present disclosure includes the carrier module 10 and the laser generating module 11. The carrier module 10 can be a carrier of a general cutting device and is used to carry an object to be cut. The object to be cut is exemplified as the composite material 2 in this embodiment. However, the present disclosure is not limited thereto. The laser generating module 11 can provide a laser beam D for cutting the composite material 2. The laser generating module 11 includes the laser scanning writer 110 and the laser path adjuster 111. The laser scanning writer 110 is a light source device for providing the laser source L, and the laser path adjuster 111 can be located on the scanning path of the laser source L. Furthermore, as shown in FIG. 2, the laser scanning writer 110 can include a laser generating unit 1100, a beam expanding unit 1101, a polygonal rotating mirror unit 1102, a first mirror set 1103, and a second mirror set 1104. The laser generating unit 1100 can provide the laser source L with a pulse width on the order of femtoseconds (10⁻¹⁵ seconds, fs), which can be less than 500 fs, and the pulse repetition rate (frequency) of the laser source L can be greater than, but not limited to, 1 MHz, so as to maintain a small heat affected zone (HAZ), which effectively improves the precision of laser processing. The laser source L can be an adjustable wavelength laser source, which changes according to the material of the object to be cut (such as the composite material 2). The polygonal rotating mirror unit 1102 can be a polygonal reflection mirror structure having a plurality of reflecting surfaces. The beam expanding unit 1101 is located between the laser generating unit 1100 and the polygonal rotating mirror unit 1102 for changing the diameter of the light beam of the laser source L, for example, enlarging the light beam of the laser source L. Further, a first mirror set 1103 is disposed between the laser generating unit 1100 and the beam expanding unit 1101, and a second mirror set 1104 is disposed between the polygonal rotating mirror unit 1102 and the beam expanding unit 1101. Therefore, after the light beam of the laser source L is supplied from the laser light generating unit 1100, the light beam of the laser source L is projected to the beam expanding unit 1101 by the reflection of the first mirror set 1103. Next, the size of the light beam of the laser source L is selectively adjusted or maintained by the beam expanding unit 1101, and reflected by the second mirror set 1104 to be projected to the polygonal rotating mirror unit 1102. Finally, as the polygonal rotating mirror unit 1102 rotates, the light beam of the laser source L is sequentially projected on different reflection surfaces of the polygonal rotating mirror unit 1102. The reflection surfaces rotate to be displaced within a unit time per rotation of the polygonal rotating mirror unit 1102. Therefore, incident lights having different angles and their corresponding reflection lights having different angles can be generated from the light beam of the laser source L within a unit time. That is, as the polygonal rotating mirror unit 1102 continues rotating, the light beam of the laser source L can be sequentially and repeatedly reflected by the plurality of reflecting surfaces and then be projected out.

Therefore, before performing the cutting operation, the cutting device 1 for cutting the composite material 2 according to the present disclosure can have the composite material 2 placed on the carrier module 10, and in the present embodiment, the composite material 2 can be a composite structure formed by covering multiple layers of materials (such as an oxide layer 21, a nitride layer 22 and a carbonization layer 23, etc.) on a substrate 24 (for example, a semiconductor wafer having a thickness of less than 100 μm). However, the present disclosure is not limited thereto.

Next, during the cutting operation, through the laser generating module 11, the cutting device 1 for cutting the composite material 2 according to the present disclosure can repeatedly project the laser beam D toward the composite material 2 on the carrier module 10 to form a plurality of cutting areas A on the composite material 2. In the present embodiment, when the laser generating module 11 repeatedly projects the laser beam D onto the composite material 2, the cutting device 1 for cutting the composite material 2 can adjust the scanning path of the laser beam D through the laser path adjuster 111, so that the laser beam D can be offset parallel to form the cutting areas A at different positions on the composite material 2. That is, the laser beam D can be adjusted by the laser path adjuster 111 to have a parallel offset relative to the composite material 2.

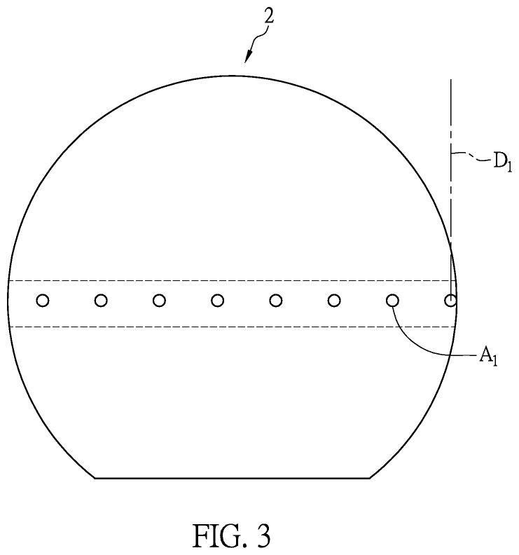

Further, as shown in FIG. 3 to FIG. 11, after the laser generating module 11 projects a laser beam D₁ to the composite material 2, a cutting area A₁ is formed on the composite material 2. Then, when the laser generating module 11 projects a laser beam D₂ to the composite material 2, the laser path adjuster 111 adjusts the scanning path of laser beam D₂, so as to cause a cutting area A₂ formed on the composite material 2 by the laser beam D₂ to be at a different position from that of the cutting area A₁, while still partially overlapping therewith. When the laser generating module 11 projects a laser beam D₃ onto the composite material 2, through the adjustment by the laser path adjuster 111, a cutting area A₃ formed by the laser beam D₃ on the composite material 2 can also be located at a different position from that of the cutting areas A₁ and A₂, while still partially overlapping with the cutting area A₂.

The afore-referenced cutting process can be regarded as the first cutting process conducted by the laser generating module 11, while the laser generating module 11 can also perform a second cutting process, in which a position of the cutting area(s) A formed by the projection of the laser beam D on the composite material 2 can be the same as that of the cutting area A₁ or the cutting area A₃, and the number of the cutting area(s) A formed by the laser generating module 11 during the second cutting process can be the same as that in the first cutting process. Therefore, the cutting device 1 for cutting the composite material 2 according to the present disclosure can perform a plurality of cutting processes by the laser generating module 11, and adjust the scanning path of the laser beam D by the laser path adjuster 111 to gradually deepen the cutting depth of the laser beam D, so as to cut through the composite material 2.

Thereby, the cutting device 1 for cutting the composite material 2 according to the present disclosure can repeatedly and continuously project a plurality of laser beams D by the laser generating module 11, and adjust the scanning paths of the laser beams D by the laser path adjuster 111, so as to form a plurality of cutting areas A on the composite material 2, and gradually deepen the cutting depth to cut through the composite material 2.

In the above embodiment, the laser source L can be infrared light (IR), ultraviolet light (UV), or green laser. However, the present disclosure is not limited thereto.

### Second Embodiment

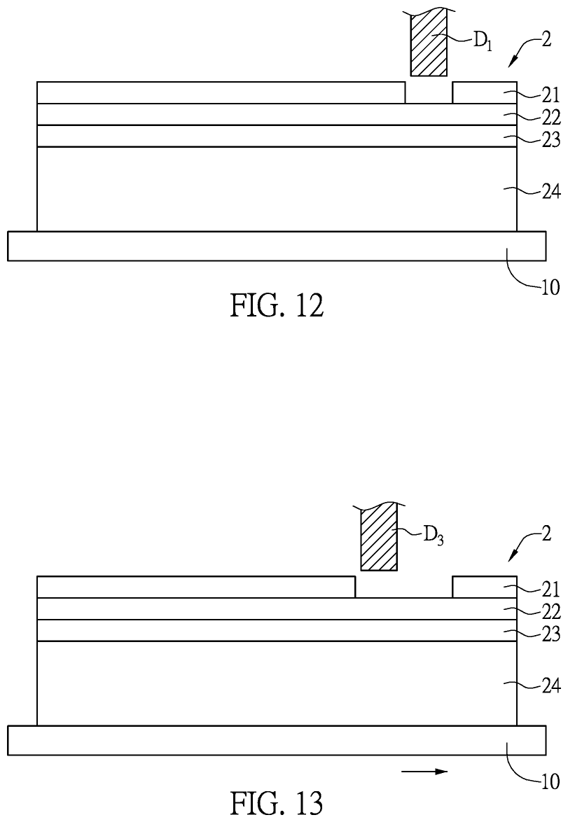

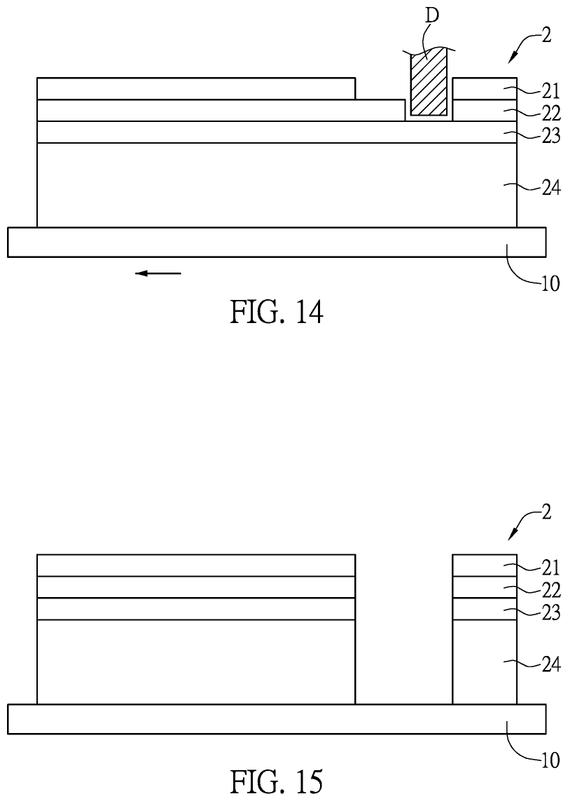

Reference is made to FIG. 12 to FIG. 15, which include the first to fourth schematic diagrams of the cutting device 1 cutting the composite material 2 by a laser beam according to a second embodiment of the present disclosure. Reference is also made to FIG. 1 to FIG. 11. As shown in the figures, in the present embodiment, the composite material 2 is offset parallel relative to the laser generating module 11 through the moving of the carrier module 10. Further, a portion of the laser beam D is projected at the same position of the composite material 2, while another portion of the laser beam D is projected at different locations of the composite material 2.

The structure and the operation principle of the cutting device 1 for cutting the composite material 2 of the present embodiment are similar to that of the first embodiment, and the cutting device 1 for cutting the composite material 2 of the present embodiment also includes the carrier module 10 and the laser generating module 11. The carrier module 10 can be a carrier of a general cutting device and is used to carry the object to be cut. The object to be cut is exemplified as the composite material 2 in this embodiment. However, the present disclosure is not limited thereto. The laser generating module 11 can provide a laser beam D for cutting the composite material 2. The laser generating module 11 includes the laser scanning writer 110 and the laser path adjuster 111. The laser scanning writer 110 is a light source device for providing the laser source L with a pulse width on the order of femtoseconds, which can be less than 500 fs, and the pulse repetition rate (frequency) of the laser source L can be greater than, but not limited to, 1 MHz. The laser path adjuster 111 can be located on the scanning path of the laser source L.

Therefore, before performing the cutting operation, the cutting device 1 for cutting the composite material 2 according to the present embodiment can have the composite material 2 placed on the carrier module 10, and the composite material 2 can be a composite structure formed by covering multiple layers of materials (such as the oxide layer 21, the nitride layer 22 and the carbonization layer 23, etc.) on the substrate 24 (for example, a semiconductor wafer having a thickness of less than 100 μm). However, the present disclosure is not limited thereto.

One of the differences between the cutting device 1 for cutting the composite material 2 of the present embodiment and that of the foregoing first embodiment is that, when the cutting device 1 of the present embodiment performs cutting, the composite material 2 can be offset parallel relative to the laser generating module 11 through the moving of the carrier module 10, so that the cutting area A formed by projecting the laser beam D onto the composite material 2 is offset parallel, and a plurality of laser beams D are sequentially projected onto the composite material 2 to cut the composite material 2.

Further, when performing cutting, the cutting device 1 for cutting the composite material 2 according to the present disclosure can repeatedly project the laser beam D by the laser generating module 11 onto the composite material 2 on the carrier module 10, and form a plurality of cutting areas A on the composite material 2. In the present embodiment, during the process of the laser generating module 11 repeatedly projecting the laser beam D to the composite material 2, the composite material 2 is offset parallel relative to the laser generating module 11 by the moving of the composite material 2 and the carrier module 10, so that the laser beam D can be offset parallel, thereby forming the cutting area A at different positions on the composite material 2.

Further, as shown in FIG. 3 to FIG. 7 and FIG. 12 to FIG. 15, after the laser generating module 11 projects the laser beam D₁ to the composite material 2, the laser beam D₁ forms a cutting area A₁ on the composite material 2. Then, when the laser generating module 11 projects the laser beam D₂ to the composite material 2, the composite material 2 is carried and moved by the carrier module 10, and the cutting area A₂ formed by the laser beam D₂ on the composite material 2 is located at a position different from that of the cutting area A₁, while still partially overlapping therewith. When the laser generating module 11 projects the laser beam D₃ to the composite material 2, the composite material 2 is carried and moved by the carrier module 10, and the cutting area A₃ formed by the laser beam D₃ on the composite material 2 is located at a position different from that of the cutting areas A₁ and A₂, while still partially overlapping with that of the cutting area A₂. The afore-referenced cutting process can be regarded as the first cutting process conducted by the laser generating module 11, while the laser generating module 11 can also perform a second cutting process, that is, a position of the cutting area(s) A formed by the projection of the laser beam D on the composite material 2 can be the same as that of the cutting area A₁ or the cutting area A₃, and the number of the cutting area(s) A formed by the laser generating module 11 during the second cutting process can be the same as that in the first cutting process. Therefore, the cutting device 1 for cutting the composite material 2 according to the present disclosure can perform a plurality of cutting processes by the laser generating module 11, and adjust the scanning path of the laser beam D by the laser path adjuster 111 to gradually deepen the cutting depth of the laser beam D, so as to cut through the composite material 2.

Thereby, the cutting device 1 for cutting the composite material 2 according to the present disclosure can repeatedly and continuously project a plurality of laser beams D by the laser generating module 11, and adjust the scanning paths of the laser beams D by the laser path adjuster 111, so as to form a plurality of cutting areas A on the composite material 2, and gradually deepen the cutting depth to cut through the composite material 2.

In the above embodiment, the laser source L can be IR, UV or green laser. However, the present disclosure is not limited thereto.

Through the technical features of “a laser generating module 11 for providing a laser beam D,” “the laser generating module 11 includes a laser scanning writer 110 for providing a laser source L and a laser path adjuster 111 on the scanning path of the laser source L,” and “the cutting area A formed by projecting the laser beam D on the composite material 2 is offset parallel by the adjustment of the projecting of the laser beam D by the laser path adjuster 111, or the moving of the composite material 2 through the carrier module 10,” the cutting device 1 for cutting the composite material 2 provided by the present disclosure can form a plurality of the cutting area A at different positions on the composite material 2, and gradually deepen the depth of the cutting by repeated and continuing projecting of the laser beam D, so as to cut through the composite material 2.

Furthermore, the cutting device 1 for cutting a composite material of the present disclosure can carry the composite material 2 through the carrier module 10, repeatedly and continuously project the laser beam D to the composite material 2 on the carrier module 10 through the laser generating module 11, and form a plurality of cutting areas A on the composite material 2. The cutting device 1 according to the present disclosure adjusts the scanning path of the laser beam D by the laser path adjuster 111, or produces parallel offset of the composite material 2 relative to the laser generating module 11 through the carrier module 10, such that the cutting area A formed by the laser beam D being projected on the composite material 2 can be offset parallel, that is, forming the cutting area at the same or different position(s) on the composite material 2, so as to cut the composite material 2. Thereby, the cutting device 1 for cutting a composite material of the present disclosure can have better cutting efficiency and maintain better integrity of an object to be cut than conventional cutting devices and cutting methods.

The foregoing description of the exemplary embodiments of the present disclosure has been presented only for the purposes of illustration and description and is not intended to be exhaustive or to limit the present disclosure to the precise forms disclosed. Many modifications and variations are possible in light of the above teaching.

Certain embodiments were chosen and described in order to explain the principles of the present disclosure and their practical application so as to enable others skilled in the art to utilize the present disclosure and various embodiments and with various modifications as are suited to the particular use contemplated. Alternative embodiments will become apparent to those skilled in the art to which the present disclosure pertains without departing from its spirit and scope.

What is claimed is:

1. A cutting device for cutting a composite material, comprising:
a carrier module for carrying the composite material; and
a laser generating module configured to provide a laser beam and including:
a laser scanning writer for providing a laser source; and
a laser path adjuster located on a scanning path of the laser source,
wherein the laser path adjuster adjusts the scanning path of the laser beam or the carrier module carries the composite material to move, so that a cutting area formed by projecting the laser beam onto the composite material is offset parallel.

2. The cutting device for cutting the composite material according to claim 1, wherein the laser beam is offset parallel relative to the composite material by the adjustment of the laser path adjuster.

3. The cutting device for cutting the composite material according to claim 1, wherein the composite material is offset parallel relative to the laser generating module by being carried and moved by the carrier module.

4. The cutting device for cutting the composite material according to claim 1, wherein a pulse width of the laser source is in the order of femtoseconds.

5. The cutting device for cutting the composite material according to claim 1, wherein a pulse width of the laser source is less than 500 femtoseconds.

6. The cutting device for cutting the composite material according to claim 1, wherein a pulse repetition rate of the laser source is higher than 1 MHz.

7. The cutting device for cutting the composite material according to claim 1, wherein the laser source is infrared light, ultraviolet light or green laser.

8. The cutting device for cutting the composite material according to claim 1, wherein the composite material includes a semiconductor wafer.

9. The cutting device for cutting the composite material according to claim 8, wherein the semiconductor wafer has a thickness less than 100 μm.

10. The cutting device for cutting the composite material according to claim 1, wherein the composite material includes at least one of an oxide layer, a nitride layer and a carbonization layer.
